(19) United States
(12) Patent Application Publication
(10) Pub. No.: US 2025/0344546 A1
(43) Pub. Date: Nov. 6, 2025

(54) SEMICONDUCTOR LIGHT-RECEIVING ELEMENT AND METHOD OF PRODUCING SAME

(71) Applicant: DOWA Electronics Materials Co., Ltd., Chiyoda-ku, Tokyo (JP)

(72) Inventors: Yoshihiko MORIYA, Akita City, AKITA (JP); Masayuki NAKANO, Akita City, AKITA (JP)

(73) Assignee: DOWA Electronics Materials Co., Ltd., Chiyoda-ku, Tokyo (JP)

(21) Appl. No.: 18/866,557

(22) PCT Filed: Jun. 9, 2023
(86) PCT No.: PCT/JP2023/021600

§ 371 Date: Nov. 18, 2024

(30) Foreign Application Priority Data
Jun. 14, 2022 (JP) 2022-095932

(51) Int. Cl. H10F 77/124; H10F 30/22; H10F 71/00; H10F 77/40

(52) U.S. Cl. CPC H10F 77/1243; H10F 30/22; H10F 71/127; H10F 77/413

(57) ABSTRACT

Provided is a semiconductor light-receiving element having high light reception sensitivity and high ESD withstand voltage. The semiconductor light-receiving element (100) includes an n-type InP substrate (110), an n-type InGaAs light-absorbing layer (130), and an InP window layer (140). A p-type impurity diffusion region (150) that reaches an upper part of the n-type InGaAs light-absorbing layer (130) is formed in the InP window layer (140). The n-type InGaAs light-absorbing layer (130) has a thickness of 2.2 μm or more and a carrier density due to an n-type impurity of 2.5×10¹⁵/cm³ or more.

### TECHNICAL FIELD

The present disclosure relates to a semiconductor light-receiving element and a method of producing the same, and, in particular, relates to a semiconductor light-receiving element having an infrared region as a light reception wavelength and a method of producing the same.

### BACKGROUND

Semiconductor light-receiving elements are widely used, and photodiodes for optical fibers and infrared sensors constitute representative examples of semiconductor light-receiving elements having an infrared region as a light reception wavelength.

For example, Patent Literature (PTL) 1 discloses a semiconductor light-receiving element including an n-type InP substrate, an n-type InP buffer layer stacked on the n-type InP substrate, an i-type (n-type) InGaAs light-absorbing layer stacked on the n-type InP buffer layer, an n-type InP cap layer stacked on the i-type (n-type) InGaAs light-absorbing layer, and a p-type impurity region that is formed through ion injection of a p-type impurity through the n-type InP cap layer and that forms a pn junction with the i-type (n-type) InGaAs light-absorbing layer.

### CITATION LIST

### Patent Literature

PTL 1: JP2005−259936A

### SUMMARY

### Technical Problem

The invention disclosed in PTL 1 is for use in an optical communication system and is directed at a problem of increasing fast responsiveness. In the case of a light-receiving element that is used in an infrared sensor (i.e., in an application other than an optical communication system), it is desirable for the light-receiving element to have high ESD withstand voltage (also referred to as electrostatic withstand voltage) and also to have high light reception sensitivity.

Accordingly, an object of the present disclosure is to provide a semiconductor light-receiving element that has high ESD withstand voltage while also maintaining light reception sensitivity and a method of producing this semiconductor light-receiving element.

### Solution to Problem

With the aim of achieving the object set forth above, the inventors focused on the carrier density of a light-absorbing layer in a semiconductor light-receiving element and also on the thickness of that layer, thereby leading to completion of the present disclosure. Specifically, although the adoption of a thin InGaAs light-absorbing layer in a semiconductor light-receiving element has increased the ESD withstand voltage that is obtained, this has also resulted in substantial reduction of light reception sensitivity. In response to this issue, the inventors discovered that when an InGaAs light-absorbing layer of at least a specific thickness is doped with an n-type impurity such as to have at least a specific carrier density, ESD withstand voltage can be significantly improved to 1500 V or higher with only limited reduction of light reception sensitivity.

The inventors found that in this manner, ESD withstand voltage can be significantly improved with little reduction of light reception sensitivity. Specifically, primary features of the present disclosure are as follows.

<1> A semiconductor light-receiving element comprising:
an n-type InP substrate;
an n-type InGaAs light-absorbing layer on the n-type InP substrate; and
an InP window layer on the n-type InGaAs light-absorbing layer, wherein
a p-type impurity diffusion region that reaches an upper part of the n-type InGaAs light-absorbing layer is formed in the InP window layer, and
the n-type InGaAs light-absorbing layer has a thickness of 2.2 μm or more and a carrier density due to an n-type impurity of 2.5×10¹⁵/cm³ or more.

<2> The semiconductor light-receiving element according to the foregoing <1>, wherein the carrier density due to the n-type impurity of the n-type InGaAs light-absorbing layer is 6.0×10¹⁵/cm³ or more.

<3> The semiconductor light-receiving element according to the foregoing <1> or <2>, wherein a p-type impurity that is contained in the p-type impurity diffusion region is Zn.

<4> The semiconductor light-receiving element according to any one of the foregoing <1> to <3>, wherein the n-type impurity that is contained in the n-type InGaAs light-absorbing layer is Si.

<5> The semiconductor light-receiving element according to any one of the foregoing <1> to <4>, wherein the thickness of the n-type InGaAs light-absorbing layer is not less than 2.7 μm and not more than 3.5 μm.

<6> A method of producing a semiconductor light-receiving element comprising:
a light-absorbing layer formation step of forming an n-type InGaAs light-absorbing layer on an n-type InP substrate;
a window layer formation step of forming an InP window layer on the n-type InGaAs light-absorbing layer; and
a diffusion region formation step of forming, in the InP window layer, a p-type impurity diffusion region that reaches an upper part of the n-type InGaAs light-absorbing layer, wherein
the n-type InGaAs light-absorbing layer that is formed in the light-absorbing layer formation step has a thickness of 2.2 μm or more and a carrier density due to an n-type impurity of 2.5×10¹⁵/cm³ or more.

<7> The method of producing a semiconductor light-receiving element according to the foregoing <6>, wherein the diffusion region formation step involves causing diffusion of a p-type impurity from a surface side of the InP window layer inside an MOCVD furnace after the InP window layer has been formed through the window layer formation step.

### Advantageous Effect

According to the present disclosure, it is possible to provide a semiconductor light-receiving element that has high light reception sensitivity and high ESD withstand voltage and a method of producing this semiconductor light-receiving element.

### BRIEF DESCRIPTION OF THE DRAWINGS

In the accompanying drawings:

FIG. 1 is a schematic cross-sectional view of a semiconductor light-receiving element in accordance with one embodiment of the present disclosure;

FIG. 2 is a schematic cross-sectional view of a semiconductor light-receiving element in accordance with a specific form of the present disclosure; and

FIG. 3 is a schematic cross-sectional view of a semiconductor light-receiving element for describing one embodiment of a production method according to the present disclosure.

### DETAILED DESCRIPTION

Prior to description of embodiments according to the present disclosure, the following points are described in advance.

### <Semiconductor Composition>

Firstly, in a case in which simply “InGaAs” is referred to in the present specification without the element composition ratio being clearly stated, this indicates any compound in which the composition ratio of the group III elements In (indium) and Ga (gallium) relative to the group V element As (arsenic) is 1:1 and in which the ratio of the group III elements In and Ga relative to each other is undefined. However, “InGaAs” may include up to 5% (molar concentration; same applies below) of Al relative to the total of In and Ga and may include up to 5% of P (phosphorus) and Sb (antimony) relative to As. Moreover, in a case in which simply “InP” is referred to, up to 5% of group III elements and group V elements other than In and P can be included. Note that values for composition ratios of group III-V elements can be measured by photoluminescence measurement, X-ray diffraction measurement, or the like.

### <Electrical Conductivity Type>

In the present specification, a layer that functions electrically as a p-type is referred to as a p-type semiconductor layer (also abbreviated as “p-type layer”), and a layer that functions electrically as an n-type is referred to as an n-type semiconductor layer (also abbreviated as “n-type layer”). On the other hand, a layer in which a specific impurity such as Si, Zn, S, Sn, or Mg has not intentionally been added is referred to as an “i-type” or “undoped”. An undoped group III-V compound semiconductor layer may contain impurities that were unavoidably mixed in during the production process. Specifically, in a case in which the dopant concentrations of both p-type impurities and n-type impurities are low, such as a case in which the carrier density is less than 2.5×10¹⁵/cm³, a layer is treated as “undoped” in the present specification. Values of impurity concentrations for Si, Sn, S, Te, Mg, Zn, etc. are taken to be values according to SIMS analysis.

### <Semiconductor Layer Thickness>

The thickness of each semiconductor layer provided in a semiconductor light-receiving element can be calculated through cross-sectional observation of a grown layer using a scanning electron microscope or a transmission electron microscope.

### <Carrier Density>

Determination of carrier density is performed by using an etching CV (ECV) measurement instrument to determine the carrier density of each layer. For example, an ECV Pro produced by Nanometrics can be used as the ECV measurement instrument. In a state in which the surface of each layer among a contact layer, a window layer, and a light-absorbing layer had been exposed through sequential removal of each layer among the contact layer and the window layer by wet etching, voltage was applied and CV measurement was performed using an electrolyte solution stipulated by the manufacturer of the ECV measurement instrument. Carrier density was calculated from the CV measurement results.

Note that the carrier density due to an n-type impurity in the present specification is a measurement value prior to p-type impurity diffusion (prior to a diffusion region formation step) and, in a semiconductor light-receiving element after p-type impurity diffusion, is taken to be the carrier density of a region that is a region other than a p-type impurity diffusion region and that is not affected by this diffusion.

In a case in which an n-type impurity in an n-type InGaAs light-absorbing layer is one or more of Si, S, Se, and Te, the activation rate of the n-type impurity is close to 100%, and there is a difference of less than 10% between the n-type impurity concentration and the carrier density due to the n-type impurity. In the present disclosure, the n-type impurity concentration as an average in a thickness direction of the n-type InGaAs light-absorbing layer according to SIMS may be taken to be the carrier density due to the n-type impurity.

Since diffusion of a p-type impurity results in a co-doped state of the p-type impurity and the n-type impurity, in a situation in which the n-type impurity concentration in each layer according to SIMS is regarded as the carrier density due to the n-type impurity, SIMS measurement may be performed with respect to inside or outside of the p-type impurity diffusion region. In the present disclosure, the entirety of an InGaAs light-absorbing layer in which an n-type impurity has been intentionally added, inclusive of a part where a p-type impurity has diffused, is expressed as an n-type InGaAs light-absorbing layer.

<p-Type Impurity Concentration in p-Type Impurity Diffusion Region>

The p-type impurity concentration in a p-type impurity diffusion region is described below using a case in which the p-type impurity is Zn as an example. The Zn concentration in a Zn diffusion region is determined by SIMS (secondary ion mass spectrometry) in a depth direction with respect to a central part of the Zn diffusion region, and the average Zn concentration in each layer is determined based on a depth direction Zn concentration profile for that layer. Note that in a case in which Zn is used as the p-type impurity, the detection rate (ionization rate) of Zn in SIMS analysis differs between a case in which the base material is InP and a case in which the base material is InGaAs. Therefore, in order to correct the absolute value of the element concentration for Zn, analysis results for InP having a known Zn concentration are used for correction of the Zn concentration in an InP layer, and analysis results for InGaAs having a known Zn concentration are used for correction of the Zn concentration in an InGaAs layer.

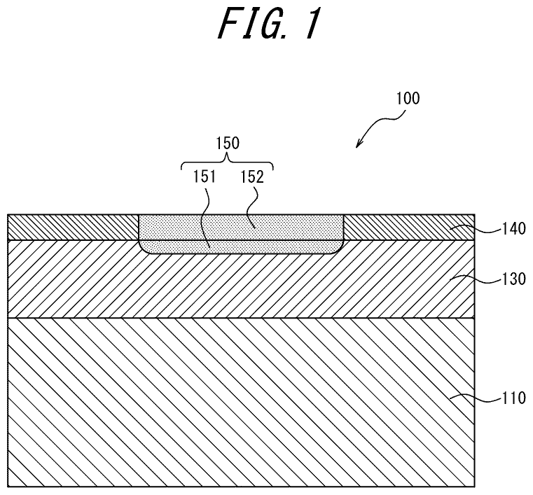

The following describes a semiconductor light-receiving element in accordance with one embodiment of the present disclosure with reference to FIG. 1. A semiconductor light-receiving element 100 in accordance with one embodiment of the present disclosure includes at least an n-type InP substrate 110, an n-type InGaAs light-absorbing layer 130 on the n-type InP substrate 110, and an InP window layer 140 on the n-type InGaAs light-absorbing layer 130. Moreover, a p-type impurity diffusion region 150 that reaches an upper part of the n-type InGaAs light-absorbing layer 130 is formed in the InP window layer 140. The n-type InGaAs light-absorbing layer 130 in the semiconductor light-receiving element 100 has a thickness of 2.2 μm or more and has a carrier density of 2.5×10¹⁵/cm³ or more. The following describes details of each configuration sequentially.

<n-Type InP Substrate>

The n-type InP substrate 110 can be a typically available n-type InP substrate. Representative examples of an n-type impurity in the n-type InP substrate 110 include S (sulfur) and Sn (tin). No specific limitations are placed on the carrier density of the n-type InP substrate 110. For example, an n-type InP substrate having a carrier density of not less than 1.0×10¹⁸/cm³ and not more than 9.0×10¹⁸/cm³ may be adopted. There are also no specific limitations on the thickness of the substrate, the diameter of the substrate, and the orientation of the substrate.

<n-Type InGaAs Light-Absorbing Layer>

The n-type InGaAs light-absorbing layer 130 is provided on the n-type InP substrate 110. The n-type InGaAs light-absorbing layer 130 has a thickness of 2.2 μm or more and has a carrier density due to an n-type impurity of 2.5×10¹⁵/cm³ or more. Even supposing that ESD withstand voltage could be slightly improved through the thickness of the n-type InGaAs light-absorbing layer 130 being thinner than 2.2 μm, this would result in reduction of light reception sensitivity due to reduction of quantum efficiency. Accordingly, the thickness of the n-type InGaAs light-absorbing layer 130 in the semiconductor light-receiving element 100 in accordance with the present disclosure is set as 2.2 μm or more, which is thicker than is typically the case, while also setting the carrier density due to the n-type impurity of the n-type InGaAs light-absorbing layer 130 at a high level of 2.5×10¹⁵/cm³ or more, which makes it possible to increase light reception sensitivity while also achieving excellent ESD withstand voltage. Note that the carrier density due to the n-type impurity of the n-type InGaAs light-absorbing layer 130 that is referred to here is the carrier density of the n-type InGaAs light-absorbing layer 130 prior to a Zn diffusion step and indicates the carrier density in a region in which Zn has not diffused (region other than the p-type impurity diffusion region 150) after the Zn diffusion step. As previously described, the thickness average Si concentration of the n-type InGaAs light-absorbing layer 130 according to SIMS may be regarded as the carrier density due to the n-type impurity. The n-type impurity with which the InGaAs light-absorbing layer 130 is doped can be Si, Ge, Sn, Pb, S, Se, or Te. Si, S, Se, and Te can preferably be used due to the ease of acquisition of source gas and the lack of diffusion during growth of the InGaAs light-absorbing layer 130 by MOCVD. Si is most preferable.

### —Composition Ratio—

A composition ratio of the n-type InGaAs light-absorbing layer 130 is denoted as Inₓ₁Ga₍₁₋ₓ₁₎As. In this case, the In composition ratio x₁ is not specifically limited so long as epitaxial growth on the n-type InP substrate 110 is possible, but it is preferable that 52.18≤x₁≤54.47, and more preferable that 52.75≤x₁≤53.89. This is because it is possible to almost match a lattice constant of the InP substrate and a lattice constant of the InGaAs layer, stress in proximity to a film interface can be reduced, and it is less likely that defects such as slip or crosshatch defects will arise. Note that the n-type impurity of the n-type InGaAs light-absorbing layer 130 may be Si, for example. The degree of lattice mismatch of the InGaAs layer relative to the InP substrate may alternatively be adopted instead of the composition ratio of the n-type InGaAs light-absorbing layer 130. The degree of lattice mismatch can be obtained from a graph of 2θ on a horizontal axis and diffracted X-ray intensity on a vertical axis that is obtained through 2θ-ω scan (diffractometer curve) measurement by X-rays with respect to (400) planes of the InP substrate 110 and the InGaAs light-absorbing layer 130 thereon. The respective lattice constants a_{InP} and a_{InGaAs} of the InP substrate and the InGaAs layer are determined from a diffraction peak position 2θ_{InP} for the InP substrate and a diffraction peak position 2θ_{InGaAs} for the InGaAs layer using the Bragg diffraction formula, the lattice constant difference is taken to be Δa=a_{InP}−a_{InGaAs}, and the degree of lattice mismatch can be evaluated through Δa/a_{InP}. More simply, in measurement results of the 2θ-ω scan, the degree of lattice mismatch can be evaluated using a diffraction angle difference Δ2θ=2θ_{InP}−2θ_{InGaAs} with the diffraction peak position of InGaAs taking the diffraction peak position of the InP substrate as a reference. Δ2θ is preferably ±200 arcsec or less, and more preferably ±100 arcsec or less. A smaller degree of lattice mismatch means that defects such as slip and crosshatch defects are less likely to arise in the InGaAs layer on the InP substrate. In addition, warping of the epi-substrate is reduced, handling in subsequent processing is facilitated, and cracking or the like of the epi-substrate after formation of a SiN film or the like can also be inhibited.

### —Thickness—

The thickness of the n-type InGaAs light-absorbing layer 130 refers to thickness that does not take into account p-type impurity diffusion and is the thickness of the n-type InGaAs light-absorbing layer 130 prior to p-type impurity diffusion. The thickness of the n-type InGaAs light-absorbing layer 130 is 2.2 μm or more as previously described, and is preferably 2.7 μm or more, and more preferably 2.75 μm or more. On the other hand, the thickness of the n-type InGaAs light-absorbing layer 130 is preferably 3.5 μm or less, and more preferably 3.45 μm or less in order to ensure ESD withstand voltage of the semiconductor light-receiving element 100. Reduction of the thickness of the n-type InGaAs light-absorbing layer 130 has an adverse effect of reducing light reception sensitivity. Moreover, an excessively large thickness makes it easier for slip and crosshatch defects to form in the InGaAs layer 130 and in the InP window layer 140 thereon. This also results in a longer growth time during formation of the InGaAs layer on the InP substrate and thus may lead to reduced throughput in production and increased production cost.

### —Carrier Density—

The carrier density due to the n-type impurity of the n-type InGaAs light-absorbing layer 130 is 2.5×10¹⁵/cm³ or more as previously described, and is preferably 3.0×10¹⁵/cm³ or more. In order to increase ESD withstand voltage, this carrier density is more preferably 6.0×10¹⁵/cm³ or more. When the carrier density due to the n-type impurity is 1.0×10¹⁶/cm³ or less, light reception sensitivity can be maintained while also increasing ESD withstand voltage. There is little effect in terms of increasing ESD withstand voltage when the carrier density due to the n-type impurity of the n-type InGaAs light-absorbing layer 130 is too low. Conversely, light reception sensitivity decreases when the carrier density due to the n-type impurity is too high.

### <InP Window Layer>

The InP window layer 140 is provided on the n-type InGaAs light-absorbing layer 130. Although the InP window layer 140 may be undoped, it is preferable that the InP window layer 140 is doped with an n-type impurity such as Si. The carrier density due to this n-type impurity is preferably not less than 5.0×10¹⁵/cm³ and not more than 1.1×10¹⁶/cm³. Note that the carrier density due to the n-type impurity of the InP window layer 140 referred to here indicates the carrier density prior to a Zn diffusion step in the same manner as for the InGaAs light-absorbing layer 130. The thickness of the InP window layer 140 is not specifically limited and can be set as 0.5 μm to 2 μm, for example. Note that although the InP window layer 140 is preferably InP, several percent of a group III or group V element may be mixed in besides InP so long as the InP window layer 140 has a sufficient band gap for transmission of a wavelength that is absorbed by the n-type InGaAs light-absorbing layer 130.

<p-Type Impurity Diffusion Region>

The p-type impurity diffusion region 150 is formed in the InP window layer 140 of the semiconductor light-receiving element 100 and reaches an upper part of the n-type InGaAs light-absorbing layer 130. More specifically, the p-type impurity diffusion region 150 is provided from an outermost surface of the InP window layer 140 to a surface layer part of the n-type InGaAs light-absorbing layer 130 in part of an in-plane direction of the InP window layer 140 as illustrated in FIG. 1. For convenience, a part of the p-type impurity diffusion region 150 that is formed in the InP window layer 140 is referred to here as a window layer-encompassed diffusion region 152 and a part of the p-type impurity diffusion region 150 that is formed in the n-type InGaAs light-absorbing layer 130 is referred to here as a light-absorbing layer-encompassed diffusion region 151.

When the p-type impurity diffusion region 150 is said to “reach” an upper part of the n-type InGaAs light-absorbing layer 130, this means that the p-type impurity of the p-type impurity diffusion region 150 has at least diffused toward a side corresponding to the n-type InP substrate 110 from an interface between the InP window layer 140 and the n-type InGaAs light-absorbing layer 130 up to a position deeper than 0.30 μm into the n-type InGaAs light-absorbing layer 130. Moreover, the p-type impurity is considered to have diffused so long as the concentration of the p-type impurity is 1.0×10¹⁸/cm³ or more. The n-type InGaAs light-absorbing layer 130 is doped with an n-type impurity, and the InP window layer 140 is also doped with an n-type impurity. Consequently, the light-absorbing layer-encompassed diffusion region 151 and the window layer-encompassed diffusion region 152 of the p-type impurity diffusion region 150 are each in a co-doped state with a p-type impurity and an n-type impurity. Note that the p-type impurity in the p-type impurity diffusion region is preferably Zn.

No specific limitations are placed on the size with which the p-type impurity diffusion region 150 is formed in an in-plane direction. In a case in which the p-type impurity diffusion region 150 is formed with a circular shape in plan view, the size can be set as not less than ∅10 μm and not more than ∅450 μm, for example. Moreover, the shape of the p-type impurity diffusion region 150 is not limited to a circular shape and may be a polygonal shape such as a triangle, a quadrilateral, or a pentagon. Note that the effects according to the present disclosure are more readily obtained when the p-type impurity diffusion region 150 has a smaller area. Accordingly, the area of the p-type impurity diffusion region 150 is preferably 159,050 μm² or less, more preferably 129,600 μm² or less, and even more preferably 62,500 μm² or less. The lower limit for the area is preferably 100 μm² or more in view of practicality and mass producibility.

The semiconductor light-receiving element 100 described above can simultaneously excel in terms of both light reception sensitivity and ESD withstand voltage as a result of optimization of the thickness of the n-type InGaAs light-absorbing layer and the carrier density due to the n-type impurity of the n-type InGaAs light-absorbing layer.

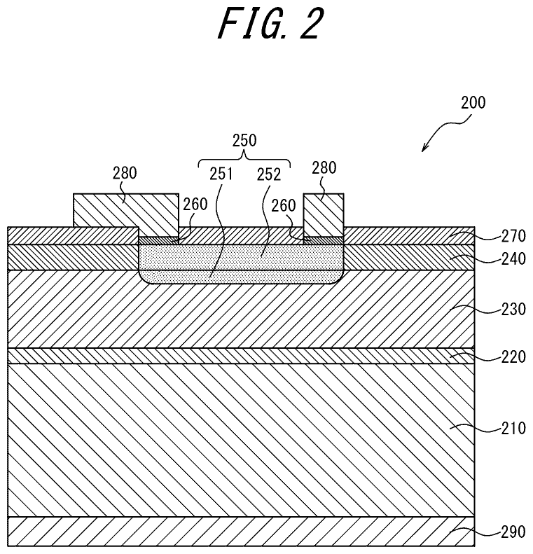

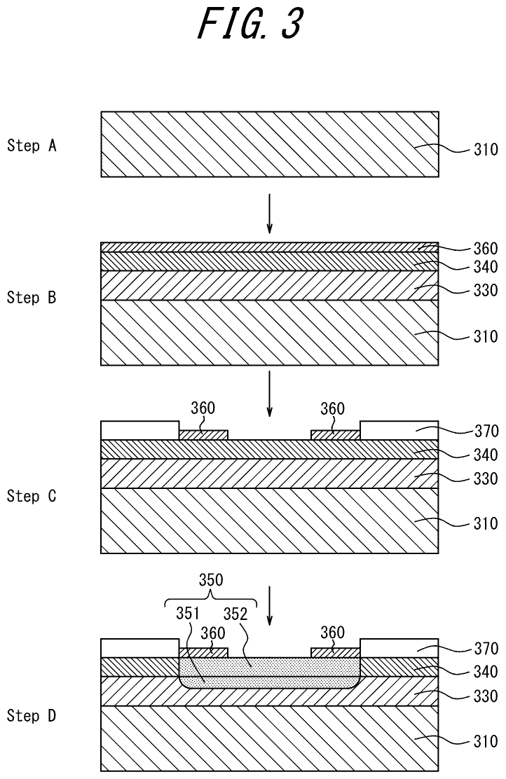

Next, a specific form that can be adopted for the semiconductor light-receiving element in accordance with the present disclosure is described with reference to FIG. 2. In the following, configurations having reference signs with the same final two digits as configurations described in the preceding embodiment are the same as those configurations, and thus repeated description thereof is omitted. Repeated description of configurations that are the same is also omitted in the same manner when referring to FIG. 3.

### <Buffer Layer>

A semiconductor light-receiving element 200 may include a buffer layer 220 between an n-type InP substrate 210 and an n-type InGaAs light-absorbing layer 230. The buffer layer 220 is preferably InP and is preferably undoped. The thickness of the buffer layer 220 can be set as not less than 0.3 μm and not more than 1.0 μm.

### <Cap Layer>

A cap layer 260 that also functions as a contact layer is preferably provided on part (for example, an edge part) of an upper surface of a p-type impurity diffusion region 250. The carrier density of the cap layer 260 prior to a Zn diffusion step is preferably less than 5.0×10¹⁵/cm³, and it is more preferable that undoped InGaAs having a carrier density of less than 2.5×10¹⁵/cm³ is used as the cap layer 260. Moreover, the thickness of the cap layer 260 can be set as not less than 50 nm and not more than 0.2 μm. When the composition ratio of the cap layer 260 is denoted as Inₓ₂Ga₍₁₋ₓ₂₎As, although no specific limitations are placed on the In composition ratio x₂ of the cap layer, it is preferable that 52.18≤x₂≤54.47, and more preferable that 52.75≤x₂≤53.89. This is because it is possible to almost match a lattice constant of the InP substrate and a lattice constant of the InGaAs layer, stress in proximity to a film interface can be reduced, and it is less likely that defects such as slip or crosshatch defects will arise in the InGaAs layer. Moreover, by causing diffusion of a p-type impurity in the cap layer 260 in a subsequently described diffusion region formation step so as to convert the cap layer 260 to a p-type and then using the cap layer 260 as a p-type contact layer, it is possible to reduce contact resistance with a p-type electrode 280.

### <AR Coat Layer>

An AR coat layer 270 for preventing reflection can be provided on part of the InP window layer 240 that is a part other than where the cap layer 260 is provided. The AR coat layer 270 is preferably SiN and can have a thickness of not less than 0.1 μm and not more than 0.5 μm.

A p-type electrode 280 can be provided at a part in contact with the cap layer 260, and an n-type electrode 290 can be provided at a rear surface of the n-type InP substrate 210. The thickness of each of these electrodes can be set as not less than 0.5 μm and not more than 4.0 μm. Ti (titanium), Pt (platinum), and Au (gold) can be used in this order from the cap layer-side as the p-type electrode 280, and a AuGe alloy or the like can be used as the n-type electrode. The shapes of the electrodes may be designed as appropriate depending on the application. For example, each of the electrodes may have a circular shape or a polygonal shape such as a triangle, quadrilateral, or pentagon, and the example illustrated in FIG. 2 is merely one example. Moreover, the p-type electrode 280 may be provided with a bonding pad for wire connection in order to cause flow of current.

When considering use of the semiconductor light-receiving element 200 for a sensor, the overall thickness of the semiconductor light-receiving element 200 is preferably set as not less than 100 μm and not more than 300 μm, the width and depth are preferably set as approximately 500 μm, and the diameter of a light-receiving part can be set as not less than ∅10 μm and not more than ∅450 μm, for example, in a case in which the light-receiving part has a circular shape in plan view. Since the light-receiving part is provided at an inner side of the p-type impurity diffusion region, the shape of the light-receiving part may be a similar shape to the shape of the p-type impurity diffusion region 150. The shape of the light-receiving part is not limited to a circular shape and may be a polygonal shape such as a triangle, quadrilateral, or pentagon.

The following refers to Steps A to D that are schematically illustrated in FIG. 3. A method of producing a semiconductor light-receiving element 300 in accordance with one embodiment of the present disclosure includes a light-absorbing layer formation step of forming an n-type InGaAs light-absorbing layer 330 on an n-type InP substrate 310, a window layer formation step of forming an InP window layer 340 on the n-type InGaAs light-absorbing layer 330, and a diffusion region formation step of forming, in the InP window layer 340, a p-type impurity diffusion region 350 that reaches an upper part of the n-type InGaAs light-absorbing layer 330. The n-type InGaAs light-absorbing layer 330 that is formed in the light-absorbing layer formation step has a thickness of 2.2 μm or more and has a carrier density due to an n-type impurity of 2.5×10¹⁵/cm³ or more.

Each semiconductor layer is preferably formed by MOCVD. The diffusion region formation step (Step D) preferably involves causing diffusion of a p-type impurity from a surface side of the InP window layer 340 using an MOCVD furnace after the InP window layer 340 has been formed through the window layer formation step. A step of forming a cap layer 360 and a step of partially removing the cap layer to partially expose the InP window layer 340 may be included prior to the diffusion region formation step (Step D), and the p-type impurity may also be caused to diffuse in the cap layer 360 in the diffusion region formation step (Step D).

An example in which Zn is adopted as the p-type impurity is specifically described as a preferred form of the diffusion region formation step. After all semiconductor layers have been epitaxially grown, Zn is caused to diffuse from an outermost surface of an epitaxial layer by MOCVD in just a desired region. In other words, in a case in which the InP window layer 340 is an uppermost semiconductor layer, Zn is caused to diffuse from the surface of the InP window layer 340, whereas in a case in which a cap layer (not illustrated) is an uppermost semiconductor layer, Zn is caused to diffuse from the surface of the cap layer. In order to cause diffusion of Zn in just a desired region, a dielectric thin film (for example, a SiO₂, SiON, or SiN film) may first be formed by CVD, a pattern may be formed with a specific shape in the dielectric thin film through photolithography using a resist, and the patterned dielectric thin film can then be used as a mask 370 during Zn diffusion. Thereafter, Zn can be caused to diffuse into the InP window layer 340 and the n-type InGaAs light-absorbing layer 330 from an outermost surface of the epitaxial layer while also passing through a cap layer in a case in which a cap layer is provided. Moreover, the cap layer 360 can be converted to a p-type through diffusion of Zn such that the cap layer 360 can suitably be used as a p-type contact layer.

In this case, a peak for Zn concentration in the n-type InGaAs light-absorbing layer 330 is observed near an interface between the InP window layer 340 and the n-type InGaAs light-absorbing layer 330, and the Zn concentration gradually decreases moving from this interface toward a side where the n-type InP substrate 310 is present. The peak concentration of Zn in the InGaAs light-absorbing layer 330 can be set as not less than 1.0×10¹⁹/cm³ and not more than 5.0×10¹⁹/cm³ according to SIMS measurement. Moreover, the average concentration of Zn in a light-absorbing layer-encompassed diffusion region 351 of the n-type InGaAs light-absorbing layer 330 can be set as not less than 8.0×10¹⁸/cm³ and not more than 4.0×10¹⁹/cm³, and is preferably not less than 9.0×10¹⁸/cm³ and not more than 3.0×10¹⁹/cm³. Note that the value for the average concentration of Zn in the light-absorbing layer-encompassed diffusion region 351 is an average value for a depth direction range from the interface between the InP window layer 340 and the n-type InGaAs light-absorbing layer 330 up to a location where the Zn concentration is 1.0×10¹⁸/cm³ in the n-type InGaAs light-absorbing layer 330. As previously described, Zn is caused to diffuse into part of a region that is doped with an n-type impurity such as Si in each semiconductor layer, and thus a window layer-encompassed diffusion region 352 where Zn has diffused into the InP window layer 340 and a light-absorbing layer-encompassed diffusion region 351 where Zn has diffused into the n-type InGaAs light-absorbing layer 330 are each in a co-doped state with Zn and an n-type impurity (for example, Si).

In the diffusion region formation step, the p-type impurity diffusion region 350 can alternatively be formed by a quartz tube sealing method or by an ion injection method instead of MOCVD.

Note that electrodes that are not illustrated in FIG. 3 can be formed by sputtering, electron beam vapor deposition, resistive heating, or the like. An AR coat layer that is not illustrated in FIG. 3 can be formed by CVD, application, or the like.

The following provides an even more detailed description of the present disclosure using examples. However, the present disclosure is not in any way limited by the following examples.

### EXAMPLES

### Example 1

Refer to the previously mentioned FIG. 2. An undoped InP buffer layer, an n-type InGaAs light-absorbing layer, an n-type InP window layer, and an undoped InGaAs cap layer were sequentially formed on an n-type InP substrate (thickness: 625 μm; carrier density: 3.0×10¹⁸/cm³) by MOCVD. Various conditions for the composition, dopant, carrier density, and thickness of each layer are shown below in Table 1. Note that the carrier density of each layer was determined by an ECV measurement instrument (ECV Pro produced by Nanometrics) prior to Zn diffusion. Next, mask formation and etching were performed with respect to the cap layer, and then a SiN film (thickness: 0.2 μm) was formed by CVD. Patterning of the SiN film was performed by photolithography using a resist, and Zn was caused to diffuse by MOCVD such that Zn diffused from the cap layer toward the n-type InP window layer and the n-type InGaAs light-absorbing layer. DEZn (diethylzinc) was used as a Zn source. Finally, a p-type electrode and an n-type electrode were formed to thereby produce a semiconductor light-receiving element according to Example 1.

TABLE 1

| | | | Carrier density | |
|---|---|---|---|---|
| | | | prior to Zn | |
| Semiconductor | | | diffusion | Thickness |
| layer | Composition | Dopant | (/cm³) | (μm) |
| InGaAs | In_{0.53}Ga_{0.47}As | (Undoped) | <5 × 10¹⁵ | 0.1 |
| cap layer | | | | |
| n-Type | InP | Si | 8.0 × 10¹⁵ | 1.0 |
| InP window | | | | |
| layer | | | | |
| n-Type | In_{0.53}Ga_{0.47}As | Si | 3.0 × 10¹⁵ | 2.8 |
| InGaAs light- | | | | |
| absorbing layer | | | | |
| Buffer layer | InP | (Undoped) | — | 0.5 |
| n-Type | InP | S | 3.0 × 10¹⁸ | 625 |
| InP substrate | | | | |

Note that the thickness direction average Zn concentration according to SIMS measurement at the center of a Zn diffusion region in the InGaAs cap layer was 5.0×10¹⁹/cm³, and the thickness direction average Zn concentration at the center of a Zn diffusion region in the InP window layer was 5.0×10¹⁸/cm³. Moreover, the depth position at which the Zn concentration was 1.0×10¹⁸/cm³ in the depth direction at the center of the Zn diffusion region was a position at a distance of 0.33 μm from an interface between the InP window layer and the InGaAs light-absorbing layer.

### Example 2

A semiconductor light-receiving element according to Example 2 was produced in the same way as in Example 1 with the exception that the carrier density of the InGaAs light-absorbing layer prior to Zn diffusion, which was 3.0×10¹⁵/cm³ in Example 1, was changed to 1.0×10¹⁶/cm³.

### Comparative Example 1

A semiconductor light-receiving element according to Comparative Example 1 was produced in the same way as in Example 1 with the exception that the carrier density of the InGaAs light-absorbing layer prior to Zn diffusion, which was 3.0×10¹⁵/cm³ in Example 1, was changed to 3.0×10¹⁴/cm³.

### Comparative Example 2

A semiconductor light-receiving element according to Comparative Example 2 was produced in the same way as in Comparative Example 1 with the exception that the thickness of the InGaAs light-absorbing layer, which was 2.8 μm in Comparative Example 1, was changed to 2.55 μm.

### Comparative Example 3

A semiconductor light-receiving element according to Comparative Example 3 was produced in the same way as in Comparative Example 1 with the exception that the thickness of the InGaAs light-absorbing layer, which was 2.8 μm in Comparative Example 1, was changed to 3.45 μm.

### (Evaluation 1: Light Reception Sensitivity)

Light reception sensitivity was measured at wavelengths of 1060 nm, 1460 nm, and 1550 nm as described below for each of Examples 1 and 2 and Comparative Examples 1 to 3.

The produced semiconductor light-receiving element is set in a prober installed inside a dark room, and a needle of a probe is brought into contact with a pad of the p-type electrode. Electrical continuity is established between the n-type electrode and a stage of the prober. First, a specific reverse voltage is applied to the p-type electrode and the n-type electrode in a state in which a light source is not present, and current (reverse current) flowing between the p-type electrode and the n-type electrode is measured. In this manner, the dark current is determined. Next, laser light sources respectively having wavelengths of 1060 nm, 1460 nm, and 1550 nm are each used to irradiate a light-receiving part of the semiconductor light-receiving element through lens focusing in a state in which a specific reverse voltage is applied to the p-type electrode and the n-type electrode, and the reverse current under photoirradiation is measured. In this manner, the photocurrent is determined. The irradiation power of the laser light is separately measured using a light-receiving element of known light reception sensitivity. Measurement values obtained as described above can be used to determine the light reception sensitivity by the following formula.

$$[ Light reception sensitivity ] ( A / W ) = ( [ Photocurrent ] - [ Dark current ] ) / [ Irradiation power ]$$

By changing the wavelength of the light source and performing measurement as described above, it is possible to determine the light reception sensitivity at each wavelength.

Note that since values for the light reception sensitivity ([wavelength]/1240 nm) in a case in which the quantum efficiency is 100% are respectively 0.855, 1.178, and 1.25 for the wavelengths of 1060 nm, 1460 nm, and 1550 nm, these values are maximum values for the light reception sensitivity at theses wavelengths. The light reception sensitivities in Table 2 correspond to quantum efficiencies within ranges of 77% to 82%, 80% to 86%, and 78% to 85% at these wavelengths, and these light reception sensitivities can be considered to be sufficiently high.

### (Evaluation 2: ESD Withstand Voltage)

ESD withstand voltage was measured for each of Examples 1 and 2 and Comparative Examples 1 to 3. Note that for each of Examples 1 and 2 and Comparative Examples 1 to 3, one chip was selected from each of 9 locations in a plane of a wafer of that example so as to obtain 9 samples. Each chip was placed in electrical continuity with a TO stem through silver paste and Au wire to prepare a test sample for ESD withstand voltage measurement. An average value was adopted as a value for ESD withstand voltage.

Measurement of ESD withstand voltage was implemented in accordance with a testing method of a human body model electrostatic discharge test of JEITA ED-4701/304A.

An electrostatic discharge automatic measurement instrument (HED-S5000 produced by Hanwa Electronic Ind. Co., Ltd.) was used in the ESD withstand voltage measurement. A calibration sample was set in order to perform calibration of the instrument.

Next, the test sample was set, and conditions of a start voltage of 100 V, an end voltage of 4,000 V, a voltage step of 100 V, a voltage application count of 3 times, an interval time of 0.5 seconds, and an application mode of positive voltage application→negative voltage application were set. The ambient temperature during measurement was 25° C.

The test voltage was applied three times, and then the current during application of a voltage of −5 V was measured. A standard for pass/fail judgment is taken to be 1 μA, and in a case in which the current is less than 1 μA, the applied voltage is increased by 100 V and the test voltage is applied once again. The applied voltage in a situation in which the current exceeded 1 μA during application of a voltage of −5 V was taken to be a value for ESD withstand voltage.

Specifically, the test voltage was first set as +100 V and was applied to the test sample three times per 0.5 seconds. Note that the test sample is discharged via a discharge circuit each time after application of each test voltage. Thereafter, the current during application of a voltage of −5 V was measured. A judgment of “pass” is made in a case in which the current is less than 1 μA. When a pass judgment was made, the test voltage was then set as −100 V, this test voltage was applied three times per 0.5 seconds, and then the current during application of a voltage of −5 V was measured. A judgement of “pass” is made in a case in which the current is less than 1 μA. When a pass judgment was made, the test voltage was next set to +200 V, this test voltage was applied three times in the same manner, and the current at −5 V was measured. When a pass judgment is made, the same is performed with the test voltage set to −200 V. This was continued while incrementally increasing the absolute value of the test voltage by 100 V until the current during application of a voltage of −5 V exceeded 1 μA.

Production conditions and measurement results for Examples 1 and 2 and Comparative Examples 1 to 3 described above are shown in Table 2.

TABLE 2

| | Light-absorbing layer | | Evaluation | | | |
|---|---|---|---|---|---|---|
| | Carrier density prior | | | | | |
| | to Zn diffusion | Thickness | Light reception sensitivity | | | ESD |
| No. | (/cm³) | (nm) | 1060 nm | 1460 nm | 1550 nm | (V) |
| Example 1 | 3.0 × 10¹⁵ | 2800 | 0.68 | 0.98 | 1.02 | 1678 |
| Example 2 | 1.0 × 10¹⁶ | 2800 | 0.66 | 0.94 | 0.98 | 2889 |
| Comparative | 3.0 × 10¹⁴ | 2800 | 0.70 | 1.01 | 1.06 | 856 |
| Example 1 | | | | | | |
| Comparative | 3.0 × 10¹⁴ | 2550 | 0.67 | 0.95 | 0.97 | 1211 |
| Example 2 | | | | | | |
| Comparative | 3.0 × 10¹⁴ | 3450 | 0.69 | 1.00 | 1.04 | 500 |
| Example 3 | | | | | | |

It can be confirmed from Table 2 that by forming a light-absorbing layer that satisfies the conditions according to the present disclosure, it was possible to achieve excellent ESD withstand voltage with almost no reduction of light reception sensitivity.

### INDUSTRIAL APPLICABILITY

A semiconductor light-receiving element according to the present disclosure is a useful element that can simultaneously excel in terms of both light reception sensitivity and ESD withstand voltage.

### REFERENCE SIGNS LIST

100, 200, 300 semiconductor light-receiving element
110, 210, 310 n-type InP substrate
220 buffer layer
130, 230, 330 n-type InGaAs light-absorbing layer
140, 240, 340 InP window layer
150, 250, 350 p-type impurity diffusion region
151, 251, 351 light-absorbing layer-encompassed diffusion region
152, 252, 352 window layer-encompassed diffusion region
260, 360 cap layer
270 AR coat layer
280 p-type electrode
290 n-type electrode
370 mask

1. A semiconductor light-receiving element comprising:
an n-type InP substrate;
an n-type InGaAs light-absorbing layer on the n-type InP substrate; and
an InP window layer on the n-type InGaAs light-absorbing layer, wherein
a p-type impurity diffusion region that reaches an upper part of the n-type InGaAs light-absorbing layer is formed in the InP window layer, and
the n-type InGaAs light-absorbing layer has a thickness of 2.2 μm or more and a carrier density due to an n-type impurity of 2.5×10¹⁵/cm³ or more.

2. The semiconductor light-receiving element according to claim 1, wherein the carrier density due to the n-type impurity of the n-type InGaAs light-absorbing layer is 6.0×10¹⁵/cm³ or more.

3. The semiconductor light-receiving element according to claim 1, wherein a p-type impurity that is contained in the p-type impurity diffusion region is Zn.

4. The semiconductor light-receiving element according to claim 1, wherein the n-type impurity that is contained in the n-type InGaAs light-absorbing layer is Si.

5. The semiconductor light-receiving element according to claim 1, wherein the thickness of the n-type InGaAs light-absorbing layer is not less than 2.7 μm and not more than 3.5 μm.

6. A method of producing a semiconductor light-receiving element comprising:
a light-absorbing layer formation step of forming an n-type InGaAs light-absorbing layer on an n-type InP substrate;
a window layer formation step of forming an InP window layer on the n-type InGaAs light-absorbing layer; and
a diffusion region formation step of forming, in the InP window layer, a p-type impurity diffusion region that reaches an upper part of the n-type InGaAs light-absorbing layer, wherein
the n-type InGaAs light-absorbing layer that is formed in the light-absorbing layer formation step has a thickness of 2.2 μm or more and a carrier density due to an n-type impurity of 2.5×10¹⁵/cm³ or more.

7. The method of producing a semiconductor light-receiving element according to claim 6, wherein the diffusion region formation step involves causing diffusion of a p-type impurity from a surface side of the InP window layer inside an MOCVD furnace after the InP window layer has been formed through the window layer formation step.
